(19) United States
(12) Patent Application Publication
(10) Pub. No.: US 2002/0036342 A1
(43) Pub. Date: Mar. 28, 2002

(54) Substrate cooling unit

(76) Inventor: Hiromichi Koide, Tokyo (JP)

Correspondence Address: FLYNN, THIEL,, BOUTELL & TANIS, P.C., 2026 Rambling Road, Kalamazoo, MI, 49008-1699, US

(21) Appl. No.: 09/946,389

(22) Filed: Sep. 5, 2001

(30) Foreign Application Priority Data
Sep. 26, 2000 (JP) 2000-292954

(51) Int. Cl. H01L 23/34

(52) U.S. Cl. 257/714

(57) ABSTRACT

Expansion and contraction of water-cooling packs are easily carried out. A three way valve is provided at the upstream side of each water-cooling pack and a check valve is provided at the downstream side of each water-cooling pack, while a second branched pipe is connected to a pump so as to suck a cooling medium of each water-cooling pack, thereby constituting a substrate cooling unit. When the upstream and downstream sides of each water-cooling pack are closed, the cooling medium is forcibly discharged from each water-cooling pack by the pump.

### BACKGROUND OF THE INVENTION

1. Field of the Invention

The invention relates to a substrate cooling unit for cooling printed circuit boards in an integrated circuit (IC) tester and the like, particularly to a negative pressure generation piping construction.

2. Related Art

A conventional substrate cooling unit for an IC tester is described with reference to FIGS. 2 to 4. FIG. 2 shows a conventional substrate cooling unit for an IC tester, and a cooling construction is illustrated in the same figure. As shown in FIG. 2, a substrate cooling unit 110 has a water-cooling unit 100. A tank 4 which can free store a cooling medium 15 (water and the like) is incorporated in the water-cooling unit 100. A pipe 20 is connected to the tank 4 for supplying the cooling medium 15 from the tank 4, and the pump 8 and the heat exchanger 7 are respectively connected to the pipe 20 midway along thereof. The tip end of the pipe 20 is exposed outside the water-cooling unit 100 and it is connected to a plurality of water-cooling packs 10, described later, so as to free supply the cooling medium 15 to the water-cooling packs 10.

Another pipe 21 is connected to each water-cooling pack 10 for letting out the cooling medium 15 from each water-cooling pack 10. The tip end of the pipe 21 enters the water-cooling unit 100 so as to return the cooling medium 15 to the tank 4. A check valve 6 is provided midway along the pipe 21.

A test head 12 of the IC tester is disposed outside the water-cooling unit 100 wherein a plurality of printed circuit boards 11 (pin cards) stand upright in the test head 12 in a radial pattern as viewed from the above. FIG. 3 shows cooling packs disposed between the printed circuit boards 11. The water-cooling packs 10 are disposed between two printed circuit boards 11 as shown in FIG. 3. Each water-cooling pack 10 has a cooling body formed of a flexible film as disclosed in Japanese Patent Laid-Open Publication No. 07-045763, wherein a cooling medium is circulated inside the cooling body and the flexible film is expanded by a pressure of the cooling medium so that the expanded flexible film is brought into contact with and press heating elements of the printed circuit board, thereby cooling the printed circuit board.

An operation of the substrate cooling unit 110 is described next. When the pump 8 is driven, the cooling medium 15 stored in the tank 4 is supplied to the heat exchanger 7 through the pipe 20. The cooling medium 15 which is cooled by the heat exchanger 7 is further supplied to each water-cooling pack 10 through the pipe 20. FIG. 4 shows a state where the water-cooling packs 10 are expanded. The water-cooling packs 10 are expanded by the cooling medium 15 supplied from the tank 4 as shown in FIG. 4. When the expanded water-cooling packs 10 are brought into contact with and press the printed circuit boards 11 so that the printed circuit boards 11 are cooled. The cooling medium 15 of each water-cooling pack 10 is returned to the tank 4 through the pipe 21 and the check valve 6. Since the cooling medium 15 is circulated while cooled by the heat exchanger 7, the printed circuit boards 11 inside the test head 12 can be cooled.

When the cooling of each printed circuit board 11 is completed or the printed circuit board is inserted into or extracted between the water-cooling packs 10, the pump 8 is stopped. When the pump 8 is stopped, a pressure inside each water-cooling pack 10 is lowered so that each water-cooling pack 10 is contracted to become in an initial state as shown in FIG. 3. Further, since a water level Lt in the tank 4 is lower than a water level Lp of each water-cooling pack 10 by the difference L, if the pump 8 is stopped, the cooling medium 15 inside each water-cooling pack 10 is naturally returned to the tank 4. If the expansion of the each water-cooling pack 10 is stopped, each printed circuit board 11 can be inserted in and extracted between the water-cooling packs 10.

When the test head 12 as shown in FIG. 2 is connected to another equipment (e.g., probe), there is a case that the test head 12 is lifted from an ordinary installing position. In this case, since the tank 4 is disposed under the water-cooling unit 100 as shown in FIG. 2, the difference L between a water level of the tank 4 and that of the water-cooling pack 10 becomes large, causing a problem that each water-cooling pack 10 can not be expanded because of the deficiency of performance of the pump 8.

If the tank 4 is positioned over the water-cooling unit 100 so as to compensate the performance of the pump 8, the difference L between a water level of the tank 4 and that of each water-cooling pack 10 becomes too small so that even if the pump 8 is stopped, the cooling medium 15 does not flow smoothly from each water-cooling pack 10 toward the pipe 21, constituting a hindrance to an expansion of each water-cooling pack 10.

### SUMMARY OF THE INVENTION

In view of the foregoing circumstances, it is an object of the invention to provide a substrate cooling unit wherein each water-cooling pack 10 can be easily expanded and contracted.

To achieve the above object, the substrate cooling unit 30 of the first aspect of the invention comprises a cooling medium storage means 4 which can free store a cooling medium 15, supply means 8 under pressure for supplying the cooling medium 15 in the cooling medium storage means 4 under pressure, first and second pipes 20, 21 through which the cooling medium 15 is circulated between the supply means 8 under pressure to the cooling medium storage means 4, each water-cooling pack 10 which is interposed midway along the first and second pipes 20, 21 and is free expanded and contracted when the cooling medium 15 is supplied to each water-cooling pack 10 and discharged from each water-cooling pack 10, wherein when each water-cooling pack 10 is expanded, it is brought into contact with each printed circuit board 11, thereby cooling the printed circuit board 11, wherein the substrate cooling unit 30 further comprises upstream side closing means 5 which free opens and closes the first pipe 20 at the upstream side of each water-cooling pack 10, downstream side closing means 6 which free opens and closes the second pipe 21 at the downstream side of each water-cooling pack 10, and suction discharge means (8, 42) for sucking and discharging the cooling medium 15 of each water-cooling pack 10 between the upstream side closing means 5 and the downstream side closing means 6.

According to the second aspect of the invention, the suction discharge means in the first aspect of the invention comprises a pump 8 which also serves as supply means 8 under pressure, a first connection pipe 42 for connecting the suction side of the pump 8 and each water-cooling pack 10 side, and connection pipe closing means 9 which free opens and closes the first connection pipe 42.

According to the third aspect of the invention, the upstream side closing means is a three way valve 5 and a second connection pipe 41 is provided for connecting between the thee way valve 5 and the cooling medium storage means 4.

### BRIEF DESCRIPTION OF THE DRAWINGS

FIG. 1 is a view typically showing an example of a substrate cooling unit.

FIG. 2 is a conventional substrate cooling unit for an IC and shows a cooling construction.

FIG. 3 is a view showing a cooling pack disposed between the printed circuit boards.

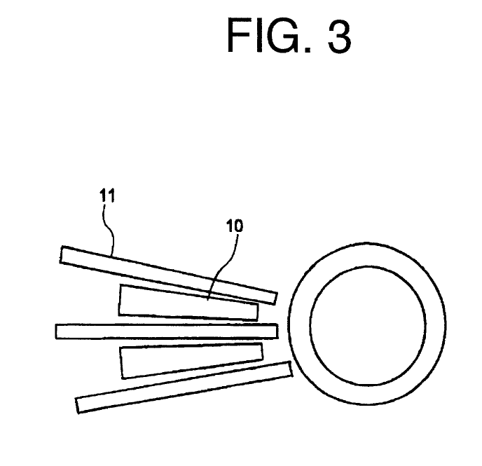

FIG. 4 is a view showing a state where the cooling pack is expanded.

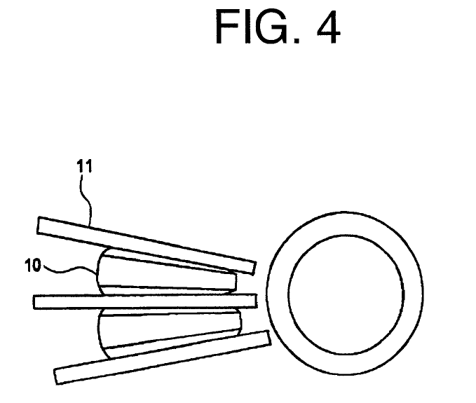

### PREFERRED EMBODIMENT OF THE INVENTION

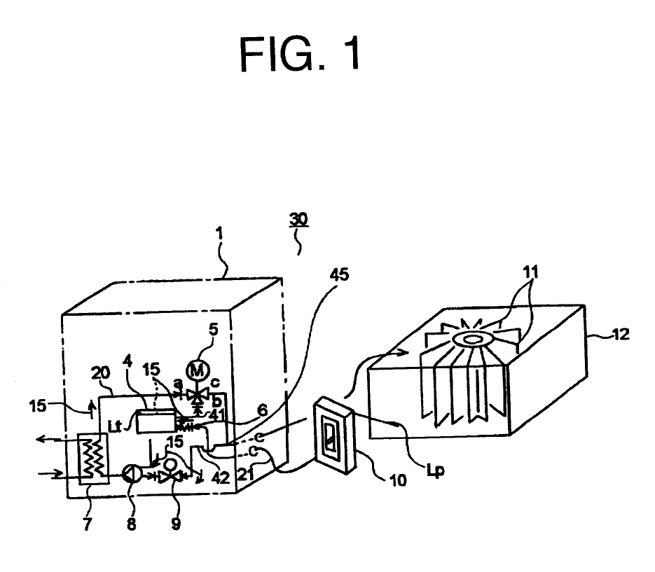

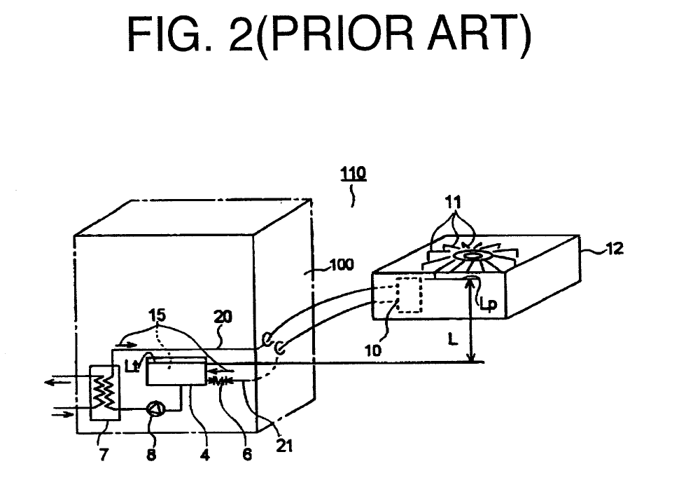

FIG. 1 is a view typically showing an example of a substrate cooling unit according to the invention. A substrate cooling unit 30 shown in FIG. 1 has components which are common to those of the substrate cooling unit 110 as explained in the Related Art and shown in FIG. 2. The components which are common to those of the substrate cooling unit 110 are depicted by the same reference numeral and the detailed explanation thereof is omitted.

A three way valve 5 having first to third ports a, b, c are provided midway along a first pipe 20 between a heat exchanger 7 and each water-cooling pack 10 and a first branched pipe 41 is connected to the second port b of the three way valve 5 in a T-shape. The tip end of the first branched pipe 41 is connected to a tank 4. A branched section 45 is provided midway along the first pipe 20 between the three way valve 5 and each water-cooling pack 10 wherein a second branched pipe 42 is connected to the branched section 45 in a T-shape. The tip end of the second branched pipe 42 is connected to a suction side of a pump 8 and a solenoid valve 9 is provided midway along the second branched pipe 42.

The tank 4, the three way valve 5, the heat exchanger 7, the pump 8, the solenoid valve 9, and the like are respectively incorporated in a water-cooling unit 1, wherein the tank 4 is disposed at a relative upper portion of the water-cooling unit 1.

An operation of the substrate cooling unit 30 shown in FIG. 1 is described next. An operation of each water-cooling pack 10 when it is expanded is first described. When the pump 8 is operated, water stored in the tank 4 is supplied to the heat exchanger 7. Cooling water in the heat exchanger 7 is supplied to the three way valve 5. Water flowing from the first port a of the three way valve 5 is supplied to each water-cooling pack 10 through the third port c of the three way valve 5. At this time, the second port b is closed. A cooling medium of each water-cooling pack 10 is returned to the tank 4 via a check valve 6. A conduit branched at the third port c is connected to the solenoid valve 9, and the solenoid valve 9 is closed when each water-cooling pack 10 is expanded.

An operation of the substrate cooling unit 30 having the foregoing construction is described now. When the pump 8 is driven, a cooling medium 15 stored in the tank 4 is supplied to each water-cooling pack 10 through the first pipe 20 via the heat exchanger 7. At this time, since the three way valve 5 is in a state where the first port a is opened, the second port check valve is closed and the third port c is opened, the cooling medium 15 is supplied to each water-cooling pack 10 through the first pipe 20. Since the solenoid valve 9 is in a closed state, the cooling medium 15 does not flow from the branched section toward the second branched pipe 42.

In such a manner, each water-cooling pack 10 is expanded by the cooling medium 15 supplied from the tank 4 and it is brought into contact with and press each printed circuit board 11, thereby cooling the printed circuit board 11. The cooling medium 15 of each water-cooling pack 10 is returned to the tank 4 through the second pipe 21 via the check valve 6. As mentioned above, the cooling medium 15 is circulated while it is cooled by the heat exchanger 7, thereby cooling each printed circuit board 11 inside a test head 12.

At this time, if the test head 12 is lifted from an ordinary installing position so as to connect to another equipment (e.g. probe), the difference between a water level Lt of the tank 4 and a water level Lp of each water-cooling pack 10 becomes large. Further, since the tank 4 is originally positioned relatively upper portion of the cooling unit 1, the difference between water levels set forth above does not become large to the extent that each water-cooling pack 10 can not be expanded because of the deficiency of performance of the pump 8.

When the cooling of each printed circuit board 11 is finished, the pump 8 is continuously operated, while the three way valve 5 is in a state where the first port a is opened, the second port b is opened and the third port c is closed. As a result, the cooling medium 15 from the first pipe 20 is returned to the tank 4 through the closing valve 40 via the three way valve 5. At this time, the solenoid valve 9 is opened. Accordingly, the pump 8 forcibly sucks water remaining in each water-cooling pack 10 via the second branched pipe 42. Since the check valve 6 is provided on the second pipe 21, even if the cooling medium 15 of the water-cooling pack 10 is sucked by the pump 8, the cooling medium 15 does not flow back from the tank 4 to each water-cooling pack 10 through the second pipe 21.

Since the cooling medium 15 of each water-cooling pack 10 is forcibly sucked by the pump 8 in such a manner, even if the difference between the water level Lt of the tank 4 and the water level Lp of each water-cooling pack 10 is small, the contraction of each water-cooling pack 10 is smoothly carried out.

According to the water-cooling pack of the first aspect of the invention, upon completion of cooling of the printed circuit boards, since the upstream side and the downstream side of each water-cooling pack are closed by the upstream side closing means and the downstream side closing means, while the cooling medium of each water-cooling pack is forcibly sucked and discharged by the suction/discharge means, the discharge of the cooling medium from each water-cooling pack is carried out smoothly irrespective of the difference between the water levels of the cooling medium between the cooling medium storage means and the water-cooling pack. Accordingly, the cooling medium storage means can be free disposed at a higher position which is convenient to supply the cooling medium under pressure to each water-cooling pack by the supply means under pressure. That is, when the substrate cooling unit of the invention is used, the expansion and contraction of each water-cooling pack can be smoothly carried out.

According to the substrate cooling unit of the second aspect of the invention, since the pump of the suction/discharge means serves also as the supply means under pressure, the substrate cooling unit can be made compact as a whole.

According to the substrate cooling unit of the third aspect of the invention, since the cooling medium can be collected by the cooling medium storage means via the thee way valve and the second connection pipe, it is very convenient.

What is claimed is:

1. A substrate cooling unit of the first aspect of the invention comprising a cooling medium storage means which can free store a cooling medium, supply means under pressure for supplying the cooling medium in the cooling medium storage means under pressure, first and second pipes through which the cooling medium is circulated between the supply means under pressure to the cooling medium storage means, each water-cooling pack which is interposed midway along the first and second pipes and is free expanded and contracted when the cooling medium is supplied to each water-cooling pack and discharged from each water-cooling pack, wherein when each water-cooling pack is expanded, it is brought into contact with leach printed circuit board, thereby cooling the printed circuit board,
wherein the substrate cooling unit further comprises upstream side closing means which free opens and closes the first pipe at the upstream side of each water-cooling pack, downstream side closing means which free opens and closes the second pipe at the downstream side of each water-cooling pack, and suction discharge means for sucking and discharging the cooling medium of each water-cooling pack between the upstream side closing means and the downstream side closing means.

2. The substrate cooling unit according to claim 1, wherein the suction discharge means comprises a pump which also serves as supply means under pressure, a first connection pipe for connecting the suction side of the pump and each water-cooling pack side, and connection pipe closing means 9 which free opens and closes the first connection pipe.

3. The substrate cooling unit according to claim 1, wherein the upstream side closing means is a three way valve and a second connection pipe is provided for connecting between the thee way valve and the cooling medium storage means.
